(19) United States
(12) Patent Application Publication
(10) Pub. No.: US 2026/0156981 A1
(43) Pub. Date: Jun. 4, 2026

(54) SEMICONDUCTOR LIGHT-EMITTING DEVICE

(71) Applicant: STANLEY ELECTRIC CO., LTD., Tokyo (JP)

(72) Inventors: Daisuke WATANABE, Tokyo (JP); Kenji TABUCHI, Tokyo (JP); Yoshihiro KOBAYASHI, Tokyo (JP)

(73) Assignee: STANLEY ELECTRIC CO., LTD., Tokyo (JP)

(21) Appl. No.: 19/403,794

(22) Filed: Nov. 29, 2025

(30) Foreign Application Priority Data
Dec. 3, 2024 (JP) 2024-210158

(51) Int. Cl. H10H 20/851; H10H 20/85; H10H 20/854

(52) U.S. Cl. CPC H10H 20/8512; H10H 20/8506; H10H 20/854

(57) ABSTRACT

Provided is a highly reliable semiconductor light-emitting device that suppresses the deterioration of a phosphor. The semiconductor light-emitting device includes a lead frame, a semiconductor light-emitting element, a framing body, and a phosphor portion. The lead frame includes a first electrode body having an element mounting surface and a second electrode body arranged separately from the first electrode body. The semiconductor light-emitting element is arranged on the element mounting surface of the first electrode body. The framing body is formed over surfaces of the first electrode body and the second electrode body. The framing body forms a recess together with the element mounting surface and a surface of the second electrode body. The phosphor portion fills the recess to cover the semiconductor light-emitting element. The phosphor portion is made of a first resin material containing a first phosphor excited by light emitted from the semiconductor light-emitting element to produce fluorescence. The first phosphor is a KSF phosphor. The first resin material is a phenyl-based silicone resin.

### BACKGROUND

### 1. Technical Field

The present invention relates to a semiconductor light-emitting device including a semiconductor light-emitting element.

### 2. Description of the Related Art

A semiconductor light-emitting device employing a lead frame is disclosed. For example, Japanese Patent No. 5766976 discloses a semiconductor light-emitting device having a lead frame, a semiconductor light-emitting element disposed on the lead frame, and a sealing material that covers the semiconductor light-emitting element on the lead frame and is made of medium resin containing a phosphor.

For example, in the semiconductor light-emitting device disclosed in Japanese U.S. Pat. No. 5,766,976, a case in which a KSF phosphor is used as the phosphor is considered. The KSF phosphor has a property of hydrolyzing when it comes into contact with moisture. Therefore, for example, if the moisture that has entered the sealing material reaches the KSF phosphor during the use of the semiconductor light-emitting device, the chromaticity of emitted light may change due to the hydrolysis of the KSF phosphor, and the desired light may not be obtained from the semiconductor light-emitting device. That is, the reliability of the semiconductor light-emitting device may decrease.

The present invention has been made in consideration of the above problem, and an object of the present invention is to provide a highly reliable semiconductor light-emitting device that suppresses the deterioration of a phosphor.

A semiconductor light-emitting device according to the present invention includes a lead frame, a semiconductor light-emitting element, a framing body, and a phosphor portion. The lead frame includes a first electrode body having an element mounting surface and a second electrode body arranged separately from the first electrode body. The semiconductor light-emitting element is arranged on the element mounting surface of the first electrode body. The framing body is formed over surfaces of the first electrode body and the second electrode body. The framing body forms a recess together with the element mounting surface and a surface of the second electrode body. The phosphor portion fills the recess to cover the semiconductor light-emitting element. The phosphor portion is made of a first resin material containing a first phosphor excited by light emitted from the semiconductor light-emitting element to produce fluorescence. The first phosphor is a KSF phosphor. The first resin material is a phenyl-based silicone resin.

### BRIEF DESCRIPTION OF THE DRAWINGS

FIG. 1 is a top view of a light-emitting device according to Embodiment 1;

FIG. 2 is a cross-sectional view of the light-emitting device according to Embodiment 1;

FIG. 3 is a cross-sectional view of the light-emitting device according to Embodiment 1;

FIG. 4 is an enlarged view of a cross-sectional surface of a constituting member of the light-emitting device according to Embodiment 1;

FIG. 5 is a table illustrating the results of verification of the light-emitting device according to Embodiment 1 and a comparative example;

FIG. 6 is a top view illustrating an exemplary manufacturing process of the light-emitting device according to Embodiment 1;

FIG. 7 is a top view illustrating the exemplary manufacturing process of the light-emitting device according to Embodiment 1;

FIG. 8 is a top view illustrating the exemplary manufacturing process of the light-emitting device according to Embodiment 1;

FIG. 9 is a top view illustrating the exemplary manufacturing process of the light-emitting device according to Embodiment 1;

FIG. 10 is a top view illustrating the exemplary manufacturing process of the light-emitting device according to Embodiment 1;

FIG. 11 is a top view illustrating the exemplary manufacturing process of the light-emitting device according to Embodiment 1;

FIG. 12 is a top view illustrating the exemplary manufacturing process of the light-emitting device according to Embodiment 1; and

FIG. 13 is a top view illustrating the exemplary manufacturing process of the light-emitting device according to Embodiment 1.

### DETAILED DESCRIPTION

The following describes embodiments of the present invention in detail with reference to the drawings. Note that the same reference numerals are given to the same components in the drawing, and the description of duplicate components is omitted.

### Embodiment 1

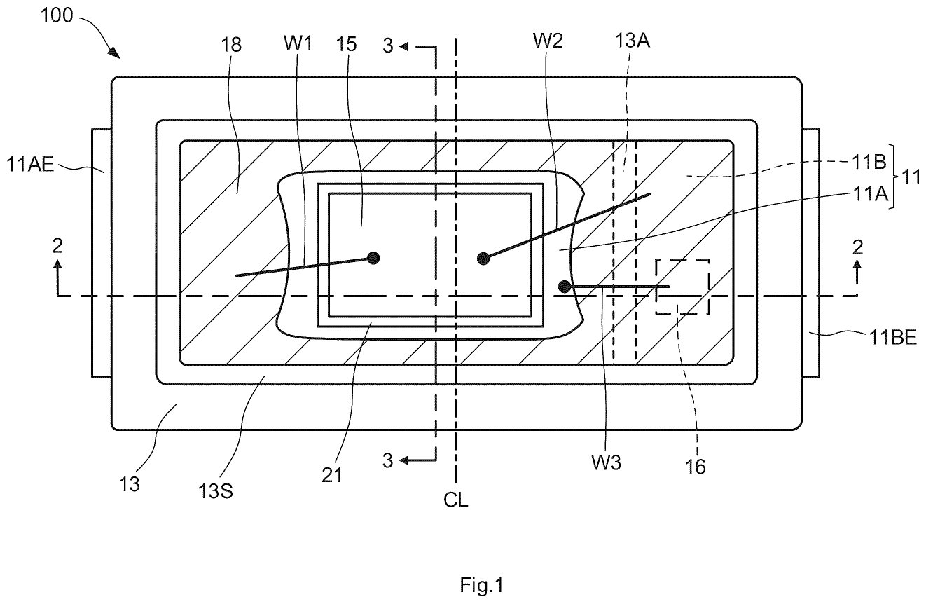

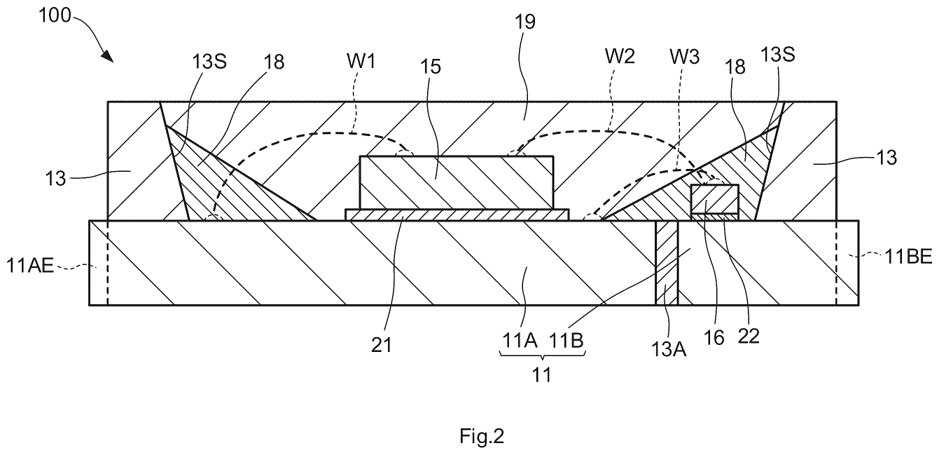

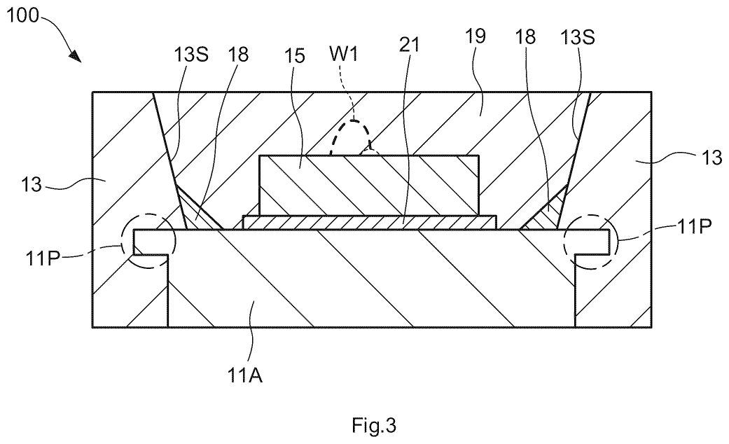

Using FIG. 1 to FIG. 3, a configuration of a light-emitting device 100 according to Embodiment 1 is described. FIG. 1 is a top view of the light-emitting device 100. FIG. 2 is a cross-sectional view taken along the line 2-2 of the light-emitting device 100 illustrated in FIG. 1. FIG. 3 is a cross-sectional view taken along the line 3-3 of the light-emitting device 100 illustrated in FIG. 1. In FIG. 2 and FIG. 3, a vertical direction in the drawings is a height direction of the light-emitting device 100.

### [Outline of Light-Emitting Device 100]

The light-emitting device 100 is configured to include a lead frame 11, a framing body 13, a light-emitting element 15, a protection element 16, a sealing body portion 18, and a phosphor portion 19. In FIG. 1, the phosphor portion 19 is omitted to avoid complicating the illustration, and the sealing body portion 18 is hatched. Also, in FIG. 1, the line segment that passes through the center of an upper surface of the light-emitting device 100 and divides the width in a left-right direction in the drawing of the light-emitting device 100 into two halves is indicated by the dash-dotted line as a center line CL.

### [Lead Frame 11]

First, a configuration of the lead frame 11 is described. The lead frame 11 is constituted of a first electrode body 11A and a second electrode body 11B that are arranged separately from one another on the same plane. Each of the first electrode body 11A and the second electrode body 11B is a metal plate having a rectangular upper surface shape. In the lead frame 11, as illustrated in FIG. 1, a short side of the first electrode body 11A is opposed to a long side of the second electrode body 11B.

A gap between the first electrode body 11A and the second electrode body 11B is filled with an insulating resin material that constitutes the framing body 13. In other words, the first electrode body 11A and the second electrode body 11B are insulated from one another by the resin material constituting the framing body 13 disposed between them.

The first electrode body 11A has a larger size than the second electrode body 11B in top view when the light-emitting device 100 is viewed from above, and the upper surface of the first electrode body 11A is a light-emitting element mounting surface on which the light-emitting element 15 is placeable. In addition, the upper surface of the second electrode body 11B is a protection element mounting surface on which the protection element 16 is placeable.

As illustrated in FIG. 3, the first electrode body 11A has protruding portions 11P that protrude laterally from side surfaces including long sides of the first electrode body 11A in an eaves-like manner. Similarly, the second electrode body 11B has protruding portions 11P that protrude laterally from side surfaces including short sides of the second electrode body 11B in an eaves-like manner (not illustrated). In other words, each of the first electrode body 11A and the second electrode body 11B has a step structure including the protruding portions 11P on the side surfaces.

Each of the first electrode body 11A and the second electrode body 11B has a foundation layer material made of copper (Cu) and is configured to have nickel (Ni) and silver (Ag) laminated on a surface of the foundation layer material in this order. Hereinafter, the notation of metal lamination on the foundation layer material is also described as Ni/Ag.

Note that aluminum (Al), an iron-nickel-cobalt alloy (Fe—Ni—Co), and the like can also be used as the foundation layer material. In addition, titanium (Ti)/gold (Au), Ni/Au, Ti/Ag, and the like can also be used on the surface of the foundation layer material.

### [Framing Body 13]

Next, the framing body 13 is described. The framing body 13 is a frame-shaped body that is formed along outer edges of the respective upper surfaces of the first electrode body 11A and the second electrode body 11B and forms a recess with the upper surfaces of the first electrode body 11A and the second electrode body 11B as a bottom surface.

An internal surface 13S, which forms the recess of the framing body 13, is inclined outward so that the space inside the recess spreads upward. That is, the recess formed by the framing body 13 and the lead frame 11 has an inverted truncated quadrangular pyramid shape recessed downward.

An end portion 11AE including a short side of the first electrode body 11A and an end portion 11BE including a long side of the second electrode body 11B project outward from sides of the framing body 13, that is, they protrude and stick out from the sides. In other words, the framing body 13 is formed to expose each of the end portion 11AE of the first electrode body 11A and the end portion 11BE of the second electrode body 11B.

As described above, the framing body 13 has a filled portion 13A that fills the gap between the first electrode body 11A and the second electrode body 11B (see FIG. 1 and FIG. 2). In addition, the framing body 13 covers both side surfaces including the long sides of the first electrode body 11A and both side surfaces including the short sides of the second electrode body 11B, that is, from the entire side surfaces to the outer edges of the respective upper surfaces of the first electrode body 11A and the second electrode body 11B, covering up the protruding portions 11P (see FIG. 3).

By providing the protruding portions 11P on the side surfaces of the first electrode body 11A and the second electrode body 11B, compared with when the protruding portions 11P are not provided, the contact area between the lead frame 11 and the framing body 13 increases when the lead frame 11 is covered by the framing body 13 similarly for both cases. This increases the fixing strength between the lead frame 11 and the framing body 13, making it difficult for the framing body 13 to detach from the lead frame 11.

In the light-emitting device 100 of the embodiment, the framing body 13 is constituted of a thermoplastic polycyclohexylene dimethylene terephthalate (PCT) resin with heat resistance as a base material (medium resin) containing titanium oxide (TiO₂) particles, which are light-scattering particles. By constituting such a material, the framing body 13 has a function of diffusely reflecting light incident on the framing body 13.

In addition, the framing body 13 has sufficient heat resistance against the heat (for example, about 240° C.) when soldering the light-emitting device 100 to a circuit board. High-melting-point nylon, such as PA6T and PA9T, and thermosetting resins, such as epoxy resins, silicone resins, and acrylic resins, can be used instead of the PCT resin.

In order to provide such a light-scattering function, the TiO₂ particles in the framing body 13 have particle sizes of 200 nm to 300 nm, and the amount of the TiO₂ particles added to the PCT resin is 16 wt % to 54 wt %, in the light-emitting device 100 of the embodiment.

### [Light-Emitting Element 15]

Next, the light-emitting element 15 is described. The light-emitting element 15 is an element that has a rectangular upper surface shape and is bonded to the upper surface of the first electrode body 11A of the lead frame 11 via an adhesive member 21. The light-emitting element 15 is a light-emitting diode (LED) having an aluminum gallium nitride (AlGaN) crystalline semiconductor structure layer containing an n-type semiconductor layer, a light-emitting layer, and a p-type semiconductor layer (all of which are not illustrated).

In the light-emitting device 100, an n-electrode (not illustrated) disposed in the n-type semiconductor layer of the semiconductor structure layer is electrically connected to the first electrode body 11A via a bonding wire W1 made of gold (Au). In addition, a p-electrode (not illustrated) disposed in the p-type semiconductor layer of the semiconductor structure layer is electrically connected to the second electrode body 11B via a bonding wire W2 made of Au.

In the light-emitting device 100, the first electrode body 11A acts as a cathode electrode, and the second electrode body 11B acts as an anode electrode. Accordingly, when a voltage is applied from the outside to supply power to the light-emitting element 15, light is emitted from the light-emitting layer of the semiconductor structure layer. When a current is applied to the light-emitting element 15, blue light with a peak wavelength of about 450 nm is emitted from the light-emitting layer.

The adhesive member 21 used to bond the light-emitting element 15 to the first electrode body 11A is constituted of a silsesquioxane (SQ)-based silicone resin as a base material containing TiO₂ particles, which are light-scattering particles. By constituting such a material, the adhesive member 21 has a function of diffusely reflecting light emitted from the light-emitting element 15 and incident on the adhesive member 21.

In addition, the SQ-based silicone resin has higher Shore hardness than PCT resins and dimethyl-based silicone resins, and stabilizes the connection part when a wire bonding connection is performed using the bonding wire W1 or the bonding wire W2.

### [Protection Element 16]

Next, the protection element 16 is described. The protection element 16 is an element that has a rectangular upper surface shape and is bonded to the upper surface of the second electrode body 11B of the lead frame 11. The protection element 16 is a Zener diode (ZD) that, when a voltage in an opposite direction is applied to an electrode of the light-emitting element 15, bypasses the current flowing in the opposite direction to avoid damage to the light-emitting element 15.

The protection element 16 has a lower surface electrode (not illustrated) disposed on a lower surface bonded to the second electrode body 11B via a conductive adhesive member 22. The adhesive member 22 is a so-called silver paste containing silver (Ag) particles, which are conductive particles, in epoxy resin. Note that a so-called epoxy solder containing tin-silver-copper (Sn—Ag—Cu) particles can also be used.

In addition, in the light-emitting device 100, an upper surface electrode (not illustrated) disposed on an upper surface of the protection element 16 is electrically connected to the first electrode body 11A via a bonding wire W3 made of Au. That is, the protection element 16 is a bidirectional ZD.

As the protection element 16, in addition to a Zener diode, a varistor (Variable Resistor) can also be used. The varistor protects the light-emitting element 15 from surge currents that can flow momentarily beyond the steady state while being supplied with power from the outside in order to drive the light-emitting element 15, and obtains a constant voltage.

### [Sealing Body Portion 18]

Next, the sealing body portion 18 is described. The sealing body portion 18 is a covering body extending from the middle of the internal surface 13S of the framing body 13 to the respective upper surfaces of the first electrode body 11A and the second electrode body 11B, and formed in a frame shape along the internal surface. That is, the sealing body portion 18 seals an interface between a frame-shaped part of the framing body 13 and the respective upper surfaces of the first electrode body 11A and the second electrode body 11B when viewed from inside the recess. The sealing body portion 18 may reach an upper end portion of the internal surface 13S of the framing body 13.

As illustrated in FIG. 1, the sealing body portion 18 covers a region of the upper surface of the first electrode body 11A, which excludes an element mounting surface on which the light-emitting element 15 is disposed, in the recess. More specifically, the sealing body portion 18 is formed to surround the light-emitting element 15 in an aspect where it does not come into contact with the adhesive member 21 or the light-emitting element 15. It is only necessary for the sealing body portion 18 not to cover an external surface of the light-emitting element 15. For example, the sealing body portion 18 may be in contact with the adhesive member 21 or may cover the adhesive member 21.

As illustrated in FIG. 1 and FIG. 2, the sealing body portion 18 covers, in the recess, the entire upper surface of the second electrode body 11B and the filled portion 13A of the framing body 13 while covering the entire surface of the protection element 16. That is, in the aspect, the sealing body portion 18 seals (covers) an end of the interface between the framing body 13 and the lead frame 11, which is exposed in the recess formed by them.

In addition, the sealing body portion 18 continuously covers the connection part of the bonding wire W1 connected to the first electrode body 11A, the connection part of the bonding wire W2 connected to the second electrode body 11B, and the connection part of the bonding wire W3 connected to the upper surface electrode of the protection element 16.

In the light-emitting device 100 of the embodiment, similarly to the adhesive member 21, the sealing body portion 18 is constituted of a silsesquioxane-based silicone resin as a base material containing TiO₂ particles, which are light-scattering particles. By constituting such a material, the sealing body portion 18 has a function of diffusely reflecting light emitted from the light-emitting element 15 and incident on the sealing body portion 18.

### [Phosphor Portion 19]

Next, the phosphor portion 19 is described. The phosphor portion 19 is a covering body formed by filling the recess formed by the lead frame 11 and the framing body 13, and covering the light-emitting element 15 and the sealing body portion 18. The height of an upper surface of the phosphor portion 19 is the same as the height of the upper surface of the frame-shaped part that forms the recess of the framing body 13.

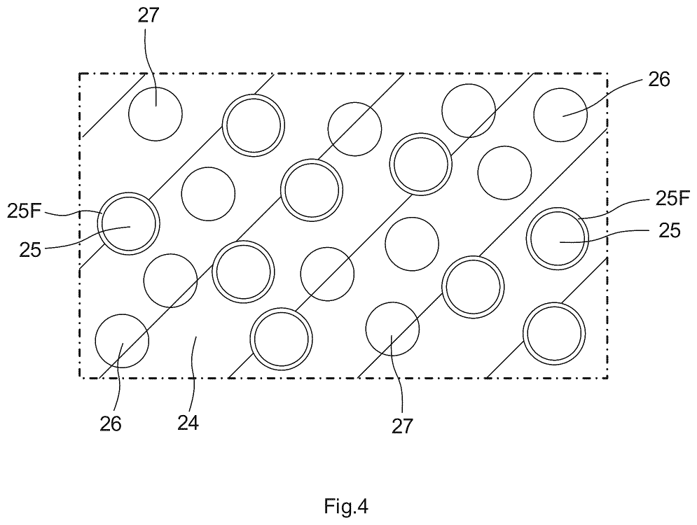

Here, a detailed configuration of the phosphor portion 19 is described with reference to FIG. 4. FIG. 4 is a drawing illustrating the configuration of the phosphor portion 19. In FIG. 4, the dash-dotted line indicates a part of a cross-sectional surface of the phosphor portion 19.

As illustrated in FIG. 4, the phosphor portion 19 is constituted of a translucent medium resin 24 containing first phosphors 25, second phosphors 26, and light-scattering particles 27 with a light-scattering property. The first phosphors 25 and the second phosphors 26 are excited by the light emitted from the light-emitting element 15 to produce fluorescence with different wavelengths from one another.

The medium resin 24 is made of phenyl-based silicone resin. Specifically, the phenyl-based silicone resin used as the medium resin 24 has a configuration in which the main chain is composed of siloxane bonds (Si—O—Si), and methyl groups (—CH₃) and phenyl groups (—C₆H₅) as side chains are bonded to silicon (Si) of the siloxane bonds, as illustrated in the following chemical formula 1.

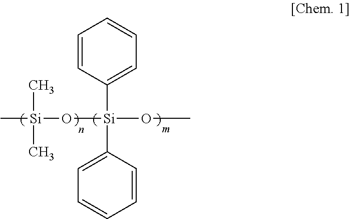

The first phosphor 25 is a phosphor that produces red fluorescence with a peak wavelength of about 630 nm in response to blue light emitted from the light-emitting element 15. In the light-emitting device 100, the first phosphor 25 is a KSF

(K₂SiF₆: Mn⁴⁺) phosphor in which manganese (Mn) as an activator agent is added to potassium silicofluoride (K₂SiF₆) that is a mother crystal.

On a surface of the first phosphor 25, a protective film 25F with translucency and moisture resistance is formed. The protective film 25F is, for example, alumina (Al₂O₃). The protective film 25F is formed, for example, by Atomic Layer Deposition (ALD). In the light-emitting device 100 of the embodiment, the protective film 25F has a thickness of 10 nm to 100 nm.

In order to further enhance the moisture resistance of the KSF phosphor constituting the first phosphor 25, the first phosphor 25 may be composed of a KSF phosphor and a K₂SiF₆ layer without Mn added, which is formed to cover a surface of the KSF phosphor, and the protective film 25F may be formed on the K₂SiF₆ layer.

The second phosphor 26 is a phosphor that produces green fluorescence with a peak wavelength of about 540 nm in response to blue light emitted from the light-emitting element 15. In the light-emitting device 100, the second phosphor 26 is a β-sialon (β-SiAlON:Eu²⁺) phosphor with europium (Eu) added as an activator agent. In the light-emitting device 100 of the embodiment, each of the first phosphors 25 and the second phosphors 26 has a particle size of 10 μm to 35 μm, and the amount of the first phosphors 25 added to the medium resin 24 and the amount of the second phosphors 26 added to the medium resin 24 are each 35 wt %. In addition, the weight compounding ratio of the first phosphors 25 and the second phosphors 26 to the medium resin 24 is 70:30.

When the blue light emitted from the light-emitting element 15 enters the phosphor portion 19, part of it directly passes through the medium resin 24, and part of it excites the first phosphors 25 and the second phosphors 26, thereby producing fluorescence from the excited phosphors.

Therefore, the excitation light that has passed through the medium resin 24 without contributing to the production of fluorescence and the fluorescence emitted from the first phosphors 25 and the second phosphors 26 are emitted from the upper surface of the phosphor portion 19. As a result, white light in which blue light, red fluorescence, and green fluorescence are mixed is emitted from the upper surface of the phosphor portion 19. That is, the upper surface of the phosphor portion 19 is a light-emitting surface of the light-emitting device 100.

In the light-emitting device 100, the light-scattering particle 27 is made of yttrium phosphate (YPO₄) with excellent forward-scattering properties. In order to make the light-scattering particle 27 moisture-resistant, a protective film made of Al₂O₃ may be formed on a surface of the light-scattering particle 27, similarly to the first phosphor 25.

In addition to YPO₄, alumina (Al₂O₃), titania (TiO₂), zirconia (ZrO₂), and the like can be used as the light-scattering particle 27. When alumina, titania, or zirconia is used, a protective film that provides moisture resistance is not required.

In the light-emitting device 100 of the embodiment, as described above, the phosphor portion 19 is constituted of the medium resin 24 made of phenyl-based silicone resin containing the first phosphors 25, which are KSF phosphors, and the second phosphors 26, which are β-sialon phosphors.

Here, KSF phosphors have a property to hydrolyze when they come into contact with moisture. Specifically, when KSF phosphors come into contact with moisture, decomposition of the KSF phosphors progresses according to the following chemical formula 2, producing manganese dioxide (MnO₂) and hydrogen fluoride (HF).

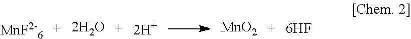

In the light-emitting device 100, as described above, the KSF phosphors and the β-sialon phosphors are excited by the excitation light (blue light) emitted from the light-emitting element 15 to produce fluorescence, thereby emitting white light in which blue light, red fluorescence, and green fluorescence are mixed from the upper surface of the phosphor portion 19.

For example, if the hydrolysis of the KSF phosphors progresses in such a light-emitting device that mixes blue, red, and green light to produce white light, the red component that constitutes white light may decrease, and the balance of blue, red, and green light emission intensities may be lost.

For example, if only the KSF phosphors undergo hydrolysis in the medium resin 24 and the red component is reduced, the light emitted from the light-emitting device 100 may shift the original chromaticity of white toward cyan (a complementary color to red), resulting in so-called chromaticity deviation. That is, there is a risk that the white light of the desired chromaticity cannot be obtained from the light-emitting device 100.

In addition, HF produced by the above chemical formula 2 has strong acidity and is harmful to a medium resin. Therefore, for example, when silicone resin is used as a medium resin, HF breaks the siloxane bonds of the silicone resin. As a result, there is a risk that softening deterioration and the like may progress due to a lowering in the molecular weight of the medium resin. For example, a low-molecular-weight medium resin can elute as bleed, leading to phenomena such as reduction in volume and discoloration of the silicone resin.

Further, MnO₂ produced by the above chemical formula 2 has a brown appearance, and when it is produced in the medium resin, the phosphor portion 19 appears to discolor to yellowish or brownish. If this happens, the translucency of the phosphor portion 19 may decrease.

When the hydrolysis of the KSF phosphors progresses in the phosphor portion 19, the chromaticity deviation of the emitted light due to the reduction in the red component, deterioration of the medium resin, and the like, as described above, may occur. As a result, there is a risk that the desired light may not be obtained from the light-emitting device 100. That is, the reliability of the light-emitting device may decrease.

In the light-emitting device 100 of the embodiment, the medium resin 24 used in the phosphor portion 19 is made of phenyl-based silicone resin as described above. The phenyl-based silicone resin used for the medium resin 24 has a so-called bulky configuration (side chains) in which the phenyl groups are three-dimensionally bulky when viewed at the molecular level. Due to such a configuration (side chains), the phenyl-based silicone resin has moisture resistance, making it difficult for moisture to penetrate into the resin.

Therefore, in the light-emitting device 100 of the embodiment, the phosphor portion 19 is formed of a medium resin with such properties, and thus, for example, even if moisture adheres to the surface of the phosphor portion 19, it is difficult for the attached moisture to penetrate. That is, it is difficult for moisture to reach the first phosphors 25, which are KSF phosphors. As a result, with the light-emitting device 100 of the embodiment, the hydrolysis of KSF phosphors is less likely to occur.

In addition, since the phenyl-based silicone resin has a bulky configuration (side chains) as described above, it can suppress the diffusion of impurities, such as corrosive gases, as well as moisture. Therefore, even if moisture permeates through the medium resin 24 of the phosphor portion 19 and the permeated moisture causes the hydrolysis of the KSF phosphors, the phenyl groups become a steric hindrance to the HF produced by the hydrolysis. This makes it difficult for the HF to reach the siloxane bonds in the silicone resin, and deterioration due to decomposition and the like of the main chain and side chains of the medium resin 24 by the HF is less likely to occur.

In the light-emitting device 100 of the embodiment, the protective films 25F made of Al₂O₃ with moisture resistance are formed on the surfaces of the first phosphors 25, which are KSF phosphors. Therefore, the moisture resistance of the first phosphors 25 themselves can be improved compared to a case where the protective films 25 are not formed. That is, the hydrolysis of the first phosphors 25 can be suppressed.

In addition, in the light-emitting device 100 of the embodiment, the interface between the lead frame 11 and the framing body 13 in the recess of the light-emitting device 100 is sealed by the sealing body portion 18. Therefore, intrusion of moisture and impurities, such as corrosive gases, through the interface into the recess can be suppressed.

Especially in the vicinity of the light-emitting element 15, the light density of blue light is high, and the temperature is high due to the heat generated by the light-emitting element 15. As a result, in that environment, the hydrolysis of the KSF phosphors is promoted. Accordingly, by providing the sealing body portion 18, the hydrolysis of the KSF phosphors in the environment can be suppressed. In addition to this, the delamination between the lead frame 11 and the framing body 13 can be avoided.

In the light-emitting device 100 of the embodiment, as described above, the moisture resistance of the medium resin 24 is improved by using a phenyl-based silicone resin for the medium resin 24, the moisture resistance of the first phosphors 25 is improved by forming the protective films 25F on the surfaces of the first phosphors 25, and intrusion of impurities due to sealing of the interface between the lead frame 11 and the framing body 13 are suppressed by the sealing body portion 18. The configuration with these three points can avoid deterioration of the phosphor portion 19. Therefore, with the light-emitting device 100 of the embodiment, a highly reliable light-emitting device can be provided.

In the light-emitting device 100 of the embodiment, it is only necessary to be able to at least achieve the improvement in the moisture resistance of the medium resin 24 by using a phenyl-based silicone resin for the medium resin 24 among the above-described three points of the configuration. It is not necessary to form the protective films 25F on the first phosphors 25 or to form the sealing body portion 18 in the recess.

In the light-emitting device 100 of the embodiment, the protection element 16 need not be provided. That is, in one aspect, only the light-emitting element 15 may be bonded to the first electrode body 11A of the lead frame 11.

### [Verification Test]

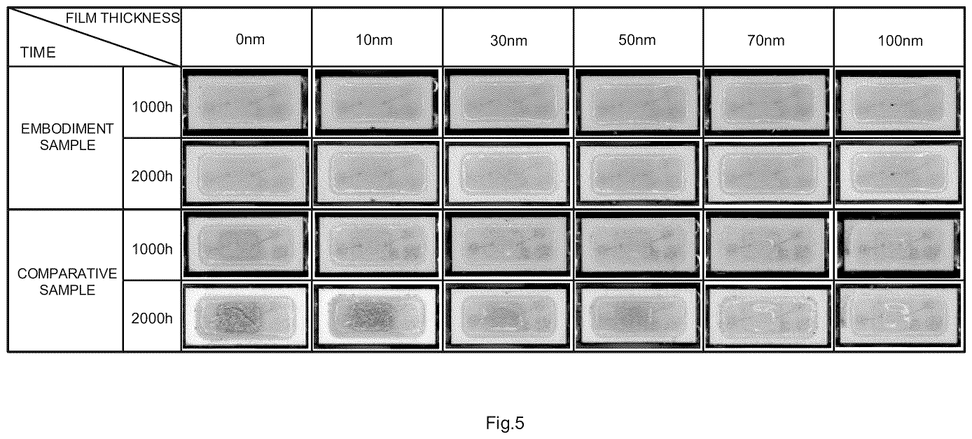

The following describes verification conducted for the light-emitting device 100 of the embodiment and a light-emitting device of a comparative example and their results, using FIG. 5. FIG. 5 is a table illustrating the photographs of upper surfaces of an embodiment sample having the configuration of the light-emitting device 100 and a comparative sample of the comparative example after the test conducted on the samples.

First, the comparative sample is described. The light-emitting device as the comparative sample differs from the light-emitting device 100 in that it employs a dimethyl-based silicone resin for the medium resin 24 used in the phosphor portion 19 of the light-emitting device 100. Other points, such as the content ratio of the first phosphors 25 (KSF phosphors) and the second phosphors 26 (β-sialon phosphors) to the medium resin 24, are the same as those of the light-emitting device 100.

Next, details of the test are described. In this test, a moisture-resistance power-on (energized) test was conducted on each of the embodiment sample and the comparative sample. Specifically, the embodiment sample and the comparative sample were placed under an environment at a temperature of 85° C. and 85% humidity, and the state of each sample after 1000 hours and 2000 hours was observed while a 170 mA current was applied to each sample.

In this test, the change of the surface state of each sample over time was confirmed when the thickness of the protective film 25F formed on the surface of the KSF phosphor, as the first phosphor 25, was set to 0 nm (no protective film 25F), 10 nm, 30 nm, 50 nm, 70 nm, and 100 nm.

From the table of FIG. 5, first, when comparing the change of the surface state over time of the embodiment sample and the comparative sample with the thickness of the protective film 25F being 0 nm, that is, with the protective film 25F not formed, the surface of the embodiment sample was not much changed between 1000 hours and 2000 hours. In comparison, discoloration of the phosphor portion 19 was confirmed in the comparative sample, especially at an elapsed time of 2000 hours.

In addition, in the comparative sample with the thickness of the protective film 25F being 10 nm to 50 nm, discoloration of the phosphor portion 19 was confirmed at an elapsed time of 2000 hours. In particular, this phenomenon was confirmed in the center of the upper surface of the phosphor portion 19, that is, in the region directly above the light-emitting element 15.

Here, although the dimethyl-based silicone resin used for the medium resin 24 in the phosphor portion 19 of the comparative sample has excellent light resistance and heat resistance, it has a property in which the gap inside the resin is large, thereby causing moisture to easily penetrate. That is, dimethyl-based silicone resins have relatively low moisture resistance properties.

The reason for the change on the surface observed at the elapsed time of 2000 hours in the comparative sample is thought to be that since dimethyl-based silicone resins have the above-described properties, moisture penetrated into the medium resin 24 of the phosphor portion 19 of the comparative sample and came into contact with the KFS phosphors contained in the medium resin 24, thereby causing the hydrolysis of the KFS phosphors. That is, it is considered that when a dimethyl-based silicone resin is used for the medium resin 24 of the phosphor portion 19, the deterioration of the phosphor portion 19 cannot be suppressed.

On the other hand, in the embodiment sample, the surface of the phosphor portion 19 did not change much even when the protective film 25F was not formed on the surface of the first phosphor 25, or when the thickness of the protective film 25F was increased. This is thought to be because the moisture resistance of the medium resin 24 was greatly improved by using a phenyl-based silicone resin as the medium resin 24, and the penetration of moisture into the phosphor portion 19 was suppressed.

Thus, in the embodiment sample having the configuration of the light-emitting device 100 of the embodiment, using a phenyl-based silicone resin for the medium resin 24 of the phosphor portion 19 allowed suppressing the degradation of the phosphor portion 19 compared to the comparative sample. In addition, in the embodiment sample, it was possible to maintain the surface state of the phosphor portion 19 in good condition by setting the thickness of the protective film 25F in a range of 10 nm to 100 nm.

### [Method for Manufacturing Light-Emitting Device 100]

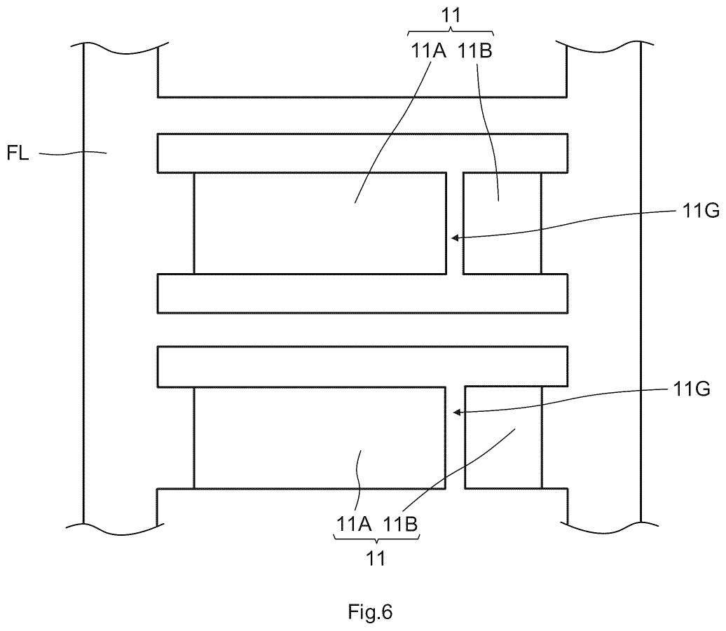

Using FIG. 6 to FIG. 13, a method for manufacturing the light-emitting device 100 is described below. Each of FIG. 6 to FIG. 13 is a top view illustrating an exemplary manufacturing process of the light-emitting device 100. While the number of the lead frames 11 continuously arranged is the same as the number of the light-emitting devices 100 manufactured at a time, only two of them are illustrated as an example in FIG. 6 to FIG. 13.

The light-emitting device 100 is manufactured according to a procedure including a lead frame preparation process, a framing body formation process, an element bonding process, a sealing body portion formation process, a phosphor portion formation process, and an individualization process. In the lead frame preparation process, a plate material including the lead frame 11 is prepared. In the framing body formation process, the framing body 13 is formed. In the element bonding process, the light-emitting element 15 and the protection element 16 are bonded to the lead frame 11. In the sealing body portion formation process, the sealing body portion 18 is formed. In the phosphor portion formation process, the phosphor portion 19 is formed.

### [Lead Frame Preparation Process]

First, one piece of plate material made of Cu is prepared, and the prepared plate material is punched out and processed with a die. Specifically, as illustrated in FIG. 6, a plate material that will form the first electrode bodies 11A and the second electrode bodies 11B is shaped in an aspect where a part of each of the first electrode bodies 11A and the second electrode bodies 11B is supported by a support frame FL.

At this time, gaps 11G are also provided between the first electrode bodies 11A and the second electrode bodies 11B. The protruding portions 11P of the first electrode bodies 11A and the second electrode bodies 11B are formed, for example, by etching the backside surfaces of the first electrode bodies 11A and the second electrode bodies 11B.

Next, a plated layer of Ni/Ag is formed on a surface of the plate material that will form the first electrode bodies 11A and the second electrode bodies 11B by electrolytic plating. Accordingly, the lead frames 11, each including the first electrode body 11A and the second electrode body 11B, are formed.

Note that metals other than Cu, such as aluminum (Al) and iron-nickel-cobalt alloys (Fe—Ni—Co), can also be used as the foundation layer material of the lead frames 11. In addition, titanium (Ti)/Au, Ni/Au, Ti/Ag, and the like can also be used as the plated layer, in addition to Ni/Ag.

Moreover, the method of processing the plate material to prepare the first electrode bodies 11A and the second electrode bodies 11B is not limited to punching with a die. The plate material may be processed, for example, by etching processing using a resist mask.

### [Framing Body Formation Process]

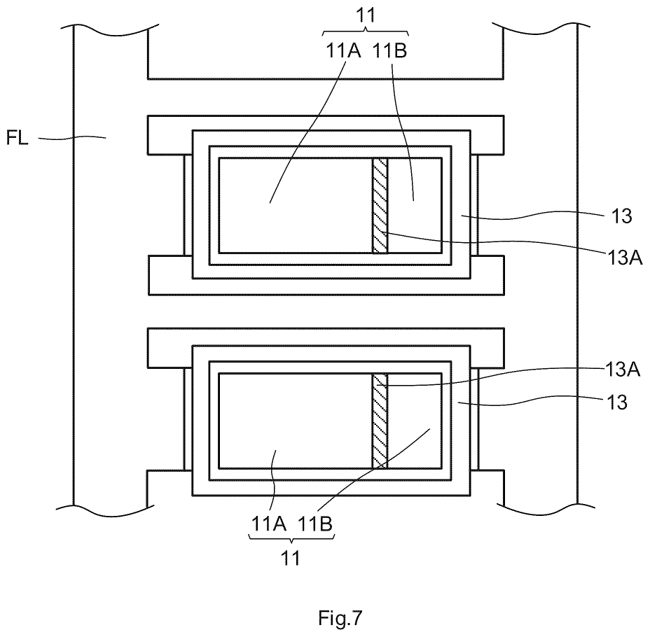

Next, as illustrated in FIG. 7, the framing bodies 13 are formed on the lead frames 11. Specifically, by insert molding, the lead frames 11 with the support frame FL are placed and fixed in a mold with a recess, and a precursor resin in which TiO₂ particles as light-scattering particles are contained in a PCT resin as a thermoplastic resin is pressed into the recess.

Then, by heating the mold at 150° C. for 120 minutes, the lead frames 11 with the framing bodies 13 formed are obtained. At this time, the filled portions 13A filling the gaps 11G between the first electrode bodies 11A and the second electrode bodies 11B are also formed.

As the medium resin for the framing bodies 13, PA6T resin and PA9T resin, which are the same thermoplastic resins, can also be used in addition to the PCT resin. Additionally, thermosetting resins, such as silicone resins, epoxy resins, and acrylic resins, can also be used. Further, in addition to TiO₂, alumina (Al₂O₃), zirconia (ZrO₂), and the like can be used as the light-scattering particles.

### [Element Bonding Process]

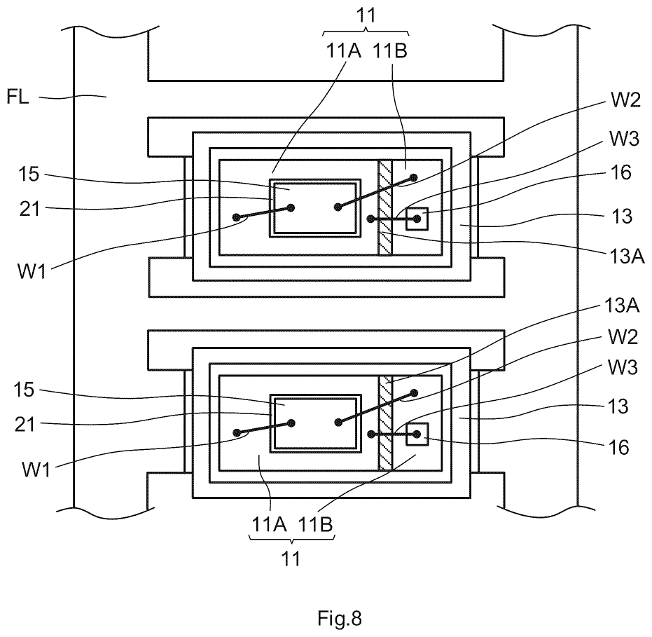

Next, as illustrated in FIG. 8, the light-emitting elements 15 and the protection elements 16 are bonded onto the lead frames 11. Specifically, the adhesive member 21, which is an insulating adhesive (die attach material), is first applied to light-emitting element mounting regions on the upper surfaces of the first electrode bodies 11A. Next, the light-emitting elements 15 are placed on the adhesive members 21 applied to the upper surfaces of the first electrode bodies 11A using a mounter.

The adhesive member 22, which is a conductive adhesive (die attach material), is then applied to protection element mounting regions on the upper surfaces of the second electrode bodies 11B. Next, the protection elements 16 are placed on the adhesive members 22 applied to the upper surfaces of the second electrode bodies 11B using a mounter. Afterward, by heating the lead frames 11 at about 180° C. for 30 minutes, the light-emitting elements 15 and the protection elements 16 are bonded and mounted.

Finally, the n-electrodes of the light-emitting elements 15 are connected to the first electrode bodies 11A via the bonding wires W1, and the p-electrodes of the light-emitting elements 15 are connected to the second electrode bodies 11B via the bonding wires W2. In addition, the upper surface electrodes of the protection elements 16 are connected to the first electrode bodies 11A via the bonding wires W3.

### [Sealing Body Portion Formation Process]

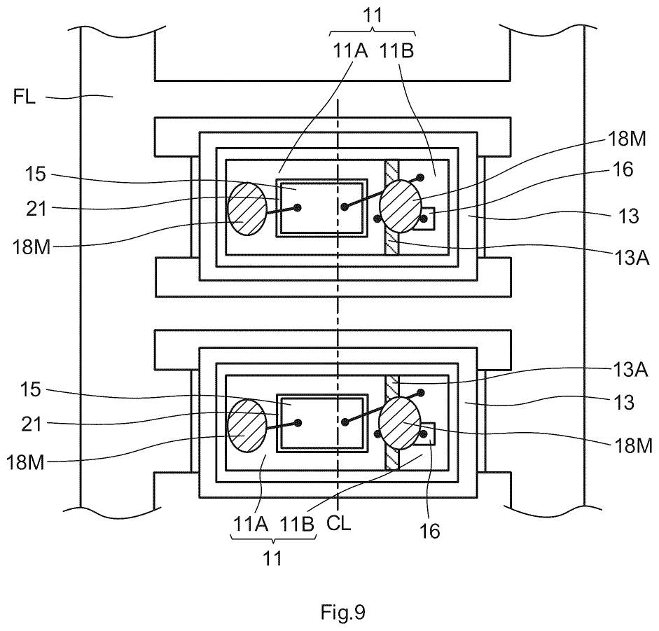

Next, the sealing body portions 18 are formed along the frame-shaped parts, which form the recesses of the framing bodies 13. First, as illustrated in FIG. 9, a precursor resin 18M is applied to short-side ends of the first electrode bodies 11A and onto the filled portions 13A of the framing bodies 13, each in an appropriate amount. In the precursor resin 18M, TiO₂ particles with particle sizes from 1 nm to 500 nm are contained in an SQ resin.

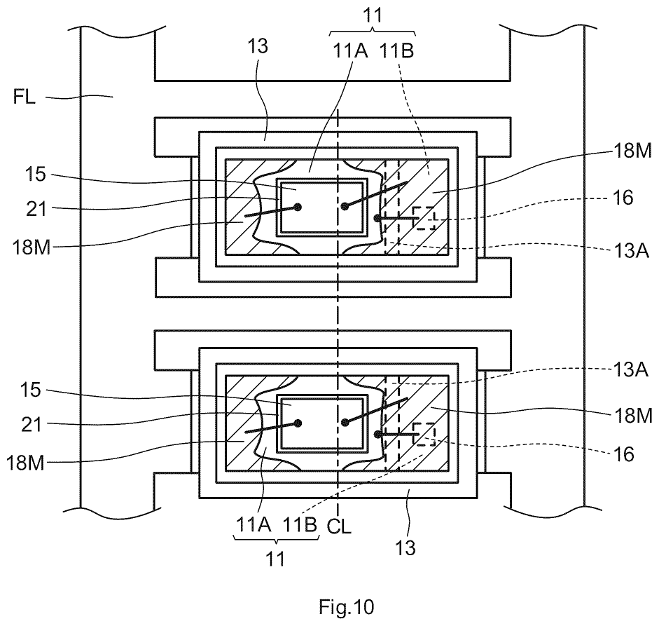

Then, as illustrated in FIG. 10, by allowing the respective precursor resins 18M applied to the short-side ends of the first electrode bodies 11A and onto the filled portions 13A of the framing bodies 13 to stand for a while, the precursor resins 18M wet and spread from the respective applied positions along the internal surfaces 13S of the framing bodies 13 mutually toward the center line CL.

Specifically, the precursor resins 18M applied to the short-side ends of the first electrode bodies 11A wet and spread to cover the interfaces between the long sides of the first electrode bodies 11A and the framing bodies 13 while covering the interfaces between the short sides of the first electrode bodies 11A and the framing bodies 13 from the applied positions.

Meanwhile, the precursor resins 18M applied onto the filled portions 13A spread to cover the interfaces between the long sides and short sides of the second electrode bodies 11B and the framing bodies 13 and the interfaces between the long sides of the first electrode bodies 11A and the framing bodies 13 while spreading along the filled portions 13A from the applied positions.

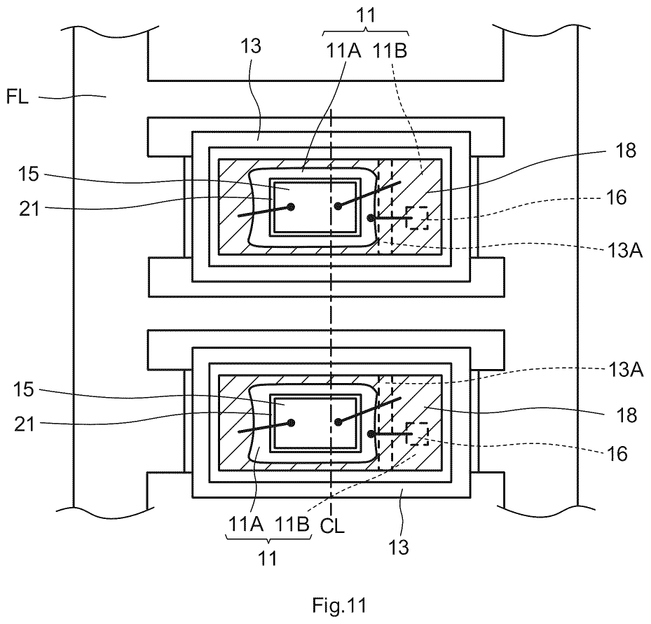

Thus, the precursor resins 18M wet and spread, thereby causing the respective precursor resins 18M applied to the short-side ends of the first electrode bodies 11A and onto the filled portions 13A of the framing bodies 13 to eventually coalesce with one another in the vicinity of the center line CL, as illustrated in FIG. 11. Then, by heating at 180° C. for five minutes, the sealing body portions 18 are formed.

At this time, the sealing body portions 18 cover the connection parts between the first electrode bodies 11A and the bonding wires W1, the connection parts between the second electrode bodies 11B and the bonding wires W2, and the connection parts between the upper surface electrodes of the protection elements 16 and the bonding wires W3. That is, in the aspect, the sealing body portions 18 seal the connection parts between the respective electrode bodies and the bonding wires W1 to W3.

### [Phosphor Portion Formation Process]

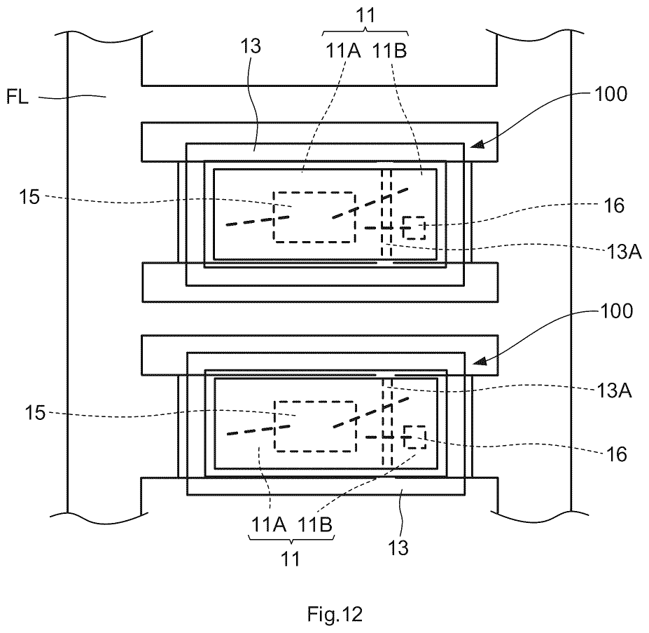

Next, as illustrated in FIG. 12, the phosphor portions 19 filling the recesses formed by the lead frames 11 and the framing bodies 13 and covering the light-emitting elements 15 are formed. Specifically, a precursor resin which becomes the phosphor portions 19 is filled into the recesses. In the precursor resin, KSF phosphors, β-sialon phosphors, and YPO₄ particles are contained in a phenyl-based silicone resin.

By filling the recesses with the precursor resin, in this aspect, the upper surfaces and side surfaces of the light-emitting elements 15 are covered by the precursor resin. Then, the phosphor portions 19 are formed by heating the precursor resin at 150° C. for one hour and hardening the resin material.

### [Individualization Process]

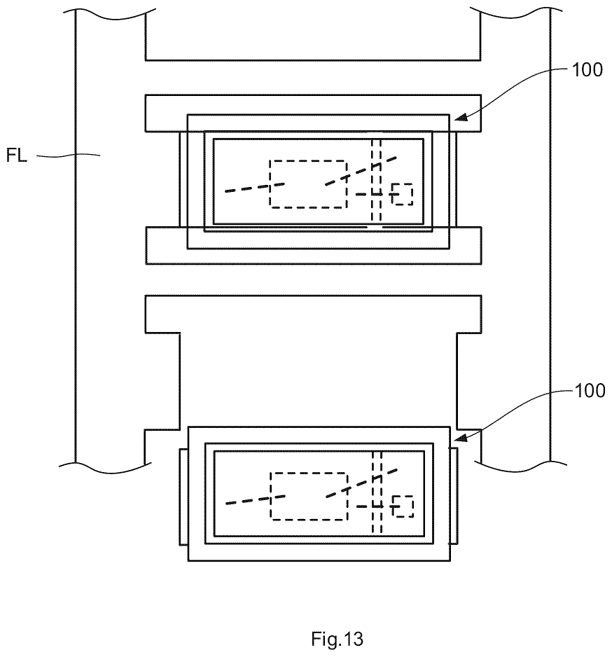

Finally, as illustrated in FIG. 13, each of the light-emitting devices 100, which are continuously arranged in the number of pieces manufactured at a time, is individualized by cutting tie bars from the support frame FL into an element unit. By the above processes, the light-emitting device 100 can be manufactured.

The light-emitting device 100 described in the above embodiment can be used, for example, as a light source in a surface mount (SMD) LED package or as a light source in a Plastic leaded chip carrier (PLCC) LED package.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2024-210158 filed on Dec. 3, 2024, the entire contents of which are incorporated herein by reference.

DESCRIPTION OF REFERENCE SIGNS

| | |
|---|---|
| 100 | Light-emitting device |
| 11 | Lead frame |
| 13 | Framing body |
| 15 | Light-emitting element |
| 16 | Protection element |
| 18 | Sealing body portion |
| 19 | Phosphor portion |
| 21, 22 | Adhesive member |
| 24 | Medium resin |
| 25 | First phosphor |
| 26 | Second phosphor |
| 27 | Light-scattering particles |

What is claimed is:

1. A semiconductor light-emitting device comprising:
a lead frame including a first electrode body having an element mounting surface and a second electrode body arranged separately from the first electrode body;
a semiconductor light-emitting element arranged on the element mounting surface of the first electrode body;
a framing body formed over surfaces of the first electrode body and the second electrode body, the framing body forming a recess together with the element mounting surface and a surface of the second electrode body; and
a phosphor portion filling the recess to cover the semiconductor light-emitting element, the phosphor portion being made of a first resin material containing a first phosphor excited by light emitted from the semiconductor light-emitting element to produce fluorescence, wherein
the first phosphor is a KSF phosphor, and
the first resin material is a phenyl-based silicone resin.

2. The semiconductor light-emitting device according to claim 1, wherein
a moisture-resistant protective film is formed on a surface of the first phosphor.

3. The semiconductor light-emitting device according to claim 2, wherein
the protective film is made of Al₂O₃.

4. The semiconductor light-emitting device according to claim 1, comprising
a sealing body portion extending from an internal surface of the framing body forming the recess to regions on the surfaces of the first electrode body and the second electrode body along the internal surface of the framing body and formed in a frame shape along the internal surface, the sealing body portion being made of a second resin material.

5. The semiconductor light-emitting device according to claim 4, wherein
the second resin material is a silsesquioxane-based silicone resin.

6. The semiconductor light-emitting device according to claim 4, wherein
the sealing body portion has the second resin material as a base material and contains light-scattering particles.

7. The semiconductor light-emitting device according to claim 1, wherein
the phosphor portion contains a second phosphor that produces fluorescence with a shorter wavelength than the first phosphor.

8. The semiconductor light-emitting device according to claim 7, wherein
the second phosphor is a β-sialon phosphor.

9. The semiconductor light-emitting device according to claim 1, wherein
the phosphor portion contains light-scattering particles with a light-scattering property.

10. The semiconductor light-emitting device according to claim 9, wherein
the light-scattering particle is made of YPO₄.

11. The semiconductor light-emitting device according to claim 9, wherein
a moisture-resistant protective film is formed on surfaces of the light-scattering particles.
